(19) United States
(12) Patent Application Publication
(10) Pub. No.: US 2009/0051285 A1
(43) Pub. Date: Feb. 26, 2009

(54) Organic electroluminescence display device

(75) Inventors: Kenta Kajiyama, Mobara (JP); Masaaki Okunaka, Fujisawa (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/230,078

(22) Filed: Aug. 22, 2008

(30) Foreign Application Priority Data
Aug. 24, 2007 (JP) 2007-217750

(51) Int. Cl. H01J 1/62

(52) U.S. Cl. 313/506

(57) ABSTRACT

An object of the present invention is to provide an organic electroluminescence (EL) display device having a high aperture ratio (ratio of light emitting area to pixel area) on both surfaces. The organic EL display device having a substrate includes on a surface of the substrate: a first organic EL element of a top emission type; a second organic EL element of a bottom emission type; a first circuit that drives the first organic EL element; and a second circuit that drives the second organic EL element. In the organic EL display device, the second circuit is arranged below the first organic EL element.

### CROSS-REFERENCE TO RELATED APPLICATION

The present application claims priority from Japanese application JP 2007-217750 filed on Aug. 24, 2007, the content of which is hereby incorporated by reference into this application.

### BACKGROUND OF THE INVENTION

1. Field of the Invention

The present invention relates to an organic electroluminescence (hereinafter, abbreviated as EL) display device.

2. Description of the Related Art

A folding mobile phone has two displays including a main display and a sub display. If those displays are realized with a single display device, thinner mobile phones may be obtained.

JP 2005-183006 A discloses two structures as double-sided light emitting display devices. One of the two structures is an active matrix organic EL display device in which a top emission type including a first reflective film is arranged on a substrate side (pixel electrode side) and a bottom emission type including the first reflective film is arranged side by side on an opposite side thereof (common electrode side), to thereby realize double-sided light emission. The other of the two structures is an active matrix organic EL display device, which realizes double-sided light emission without using the first reflective film.

JP 2005-183006 A does not disclose a plan layout of pixels. Accordingly, it is hardly to say that consideration for making a proportion of a light emitting region in the pixel (hereinafter, referred to as “aperture ratio”) to be larger is sufficiently made.

### SUMMARY OF THE INVENTION

It is an object of the present invention to provide a double-sided light emission type active matrix (hereinafter, referred to as “AM”) organic EL display device having a high aperture ratio.

The AM organic EL display device has in each pixel a circuit including a thin film transistor and a capacitor. The circuit is generally called “pixel circuit”, which controls current flowing from a power source line to an organic EL element such that the organic EL element emits light according to a gradation indicated by a data signal supplied from a data line.

In conventional technologies, the pixel circuit is arranged below a pixel isolation film (non-light emitting region) which isolates the light emitting regions in each pixel irrespective of kinds of a top emission type (hereinafter, referred to as “TE”) and a bottom emission type (hereinafter, referred to as “BE”). As a result, the gap between a TE light emitting region and a substrate remains as dead space.

Therefore, in a case where both TE and BE organic EL elements (laminated structures of light emitting regions including no pixel isolation film) are arranged side by side to be formed on a substrate, there are formed below the TE organic EL element not only a pixel circuit of the TE organic EL element but also a pixel circuit of the BE organic EL element for an effective use of the dead space. With taking this structure, the number of circuits to be arranged on the pixel isolation film is reduced, and a width of the pixel isolation film may be narrowed, thereby being capable of attaining high definition and an enhancement of the aperture ratio.

In other words, the present invention is similar to the conventional technologies in that the BE type and the TE type are formed on the same substrate to construct a screen with a first surface of the BE type and a second surface of the TE type, the second surface being a back surface of the first surface. However, the present invention is different from the conventional technologies in that the pixel circuit of the BE type is also arranged in addition to the pixel circuit of the TE type on a back surface of a first reflective film of the TE pixel, the back surface of the first reflective film being the dead space in the conventional technologies.

According to the present invention, there may be provided an organic EL display device having a high aperture ratio (ratio of light emitting area in pixel area) on both surfaces.

### BRIEF DESCRIPTION OF THE DRAWINGS

In the accompanying drawings:

FIG. 1A and FIG. 1B are pixel arrangement in a display area of an organic EL display device;

FIG. 2 is a laminated structure of two pixels including a BE pixel and a TE pixel;

FIG. 3 is an equivalent circuit diagram of a pixel circuit of a double-sided light emitting pixel;

FIG. 4 is plan layout of the double-sided light emitting pixel;

FIG. 5 is an equivalent circuit diagram of another pixel circuit of the double-sided light emitting pixel; and

FIG. 6 is plan layouts of the double-sided light emitting pixel.

### DETAILED DESCRIPTION OF THE INVENTION

Hereinafter, embodiments of the present invention are described in detail.

### First Embodiment

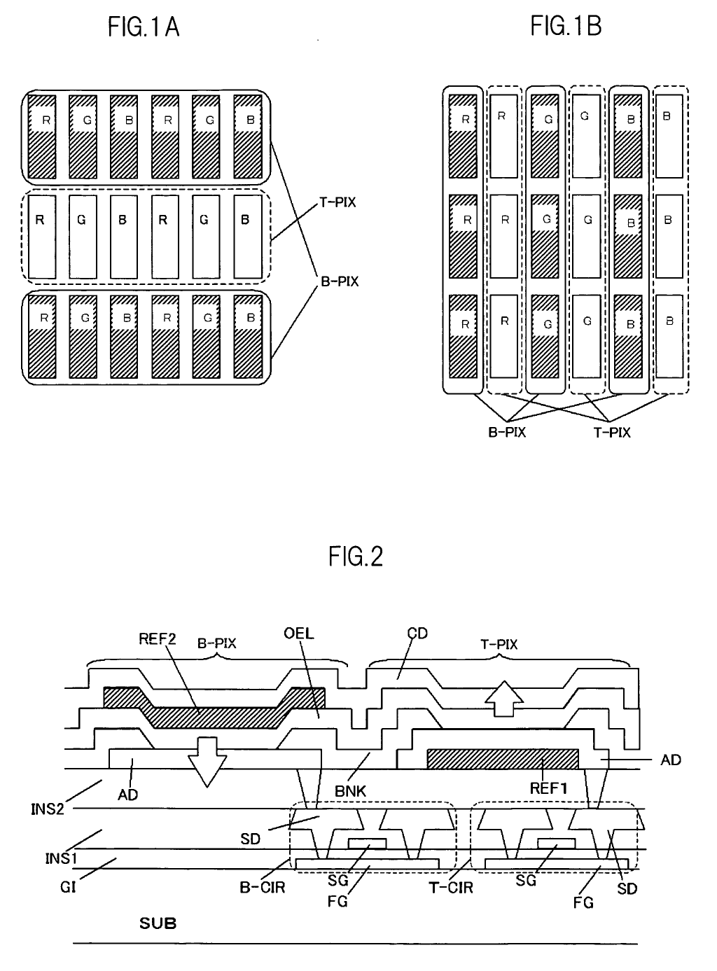

FIG. 1A and FIG. 1B show a pixel arrangement in a display area of an organic EL display device.

FIG. 1A shows a first pixel arrangement. R, G, and B shown in FIG. 1A denote a red pixel, a green pixel, and a blue pixel, respectively, and an aperture of a pixel isolation film shown in a square is an organic EL element which becomes a light emitting region. A TE organic EL element is in a first region T-PIX, and a BE organic EL element is in a second region B-PIX. Lateral stripe pixel arrays of R, G, and B are repeatedly arranged in order in a row direction of a screen, and a BE pixel array (row direction) and a TE pixel array (row direction) are alternately repeatedly arranged in a column direction.

FIG. 1B shows a second pixel arrangement. R, G, and B shown in FIG. 1B denote the red pixel, the green pixel, and the blue pixel, respectively, and the aperture of the pixel isolation film shown in a square is the organic EL element which becomes the light emitting region. The TE organic EL element is in a first region T-PIX, and the BE organic EL element is in a second region B-PIX. Stripe-like pixel arrays of R, G, and B are arranged in a column direction of a screen, and each stripe includes a vertical stripe BE pixel array (column direction) or a vertical stripe TE pixel array (column direction).

FIG. 2 shows a cross sectional structure of the two adjacent pixels in the first region T-PIX and the second region B-PIX shown in FIG. 1A and FIG. 1B.

The TE pixel in the first region T-PIX has a structure in which a substrate SUB, a polysilicon layer FG, a gate insulating film GI, a metal gate electrode layer SG, a first interlayer insulating film INS1, a source-drain metal layer SD, a second interlayer insulating film INS2, a first reflective film REF1, a pixel electrode AD, an pixel isolation film BNK, an organic EL layer OEL, and a common electrode CD are laminated in the stated order.

The BE pixel in the second region B-PIX has a structure in which the substrate SUB, the polysilicon layer FG, the gate insulating film GI, the metal gate electrode layer SG, the first interlayer insulating film INS1, the source-drain metal layer SD, the second interlayer insulating film INS2, the pixel electrode AD, the pixel isolation film BNK, the organic EL layer OEL, a second reflective film REF2, and the common electrode CD are laminated in the stated order.

The substrate SUB is a non-alkali glass with a thickness of 1.1 mm.

The polysilicon layer FG is polysilicon which is patterned in an island-like shape at a location where a thin film transistor (hereinafter, referred to as TFT), a capacitor electrode, and wiring are formed. The polysilicon is a crystallized film obtained by film-forming amorphous silicon by CVD, to be patterned by photolithography, and then being subjected to laser annealing and thermal annealing.

The gate insulating film GI is formed of a TEOS film of SiO, and is a film which is formed by CVD and patterned by photolithography so as to cover a surface of the polysilicon layer FG and the entire surface of the substrate except the polysilicon layer FG.

The metal gate electrode layer SG is formed of MoW with a thickness of 150 nm, and is film-formed by sputtering to be patterned by photolithography. The metal gate electrode layer SG is constructed as wiring supplied with a selection signal, a gate electrode, wiring within the pixel circuit, and the like. Before and after the step of forming the metal gate electrode layer SG, ion doping is performed on the polysilicon layer FG.

The first interlayer insulating film INS1 is formed of SiN. The first interlayer insulating film INS1 is obtained by performing patterning of a contact hole and the like by photolithography on a film formed on an entire upper surface of the metal gate electrode layer SG by CVD.

The source-drain metal layer SD is constructed in a laminated structure of MoW of 75 nm, AlSi of 500 nm, and MoW of 38 nm from above. The source-drain metal layer SD is a film continuously formed by sputtering, and then patterned by photolithography.

The second interlayer insulating film INS2 is formed of a laminated film including SiN (lower layer) of 400 nm and acrylic (upper layer) of 1 μm. The second interlayer insulating film INS2 is obtained by forming a film of SiN on the entire upper surface of the source-drain metal layer SD by CVD, applying acrylic thereon to be sintered, and patterning the sintered film by photolithography.

The first reflective film REF1 is formed on the second interlayer insulating film INS2 in the TE pixel first region T-PIX. The first reflective film REF1 is formed of a laminated body including AlSi with a thickness of 400 nm and MoW with a thickness of 150 nm. The laminated body is obtained by continuously forming each layer by sputtering and then patterning by photolithography to be divided for each pixel.

The pixel electrode AD is formed on the first reflective film REF1 and the second interlayer insulating film INS2 and formed of ITO with a thickness of 150 nm, which is divided for each pixel. The pixel electrode AD is formed by sputtering and then patterned by photolithography to be divided for each pixel. A lower pixel electrode AD of the TE organic EL element is also formed at the same time.

The pixel isolation film BNK, which is formed of acrylic with a thickness of 2 μm, is an insulating barrier for covering the upper surface of the second interlayer insulating film INS2 and outer edges of the pixel electrodes AD to expose the centers thereof. The pixel isolation film BNK is obtained by using a photosensitive resin composite including an acrylic polymer resin to be patterned by photolithography.

The organic EL layer OEL is obtained by laminating a hole transporting layer HTL, an organic light emitting layer EML, an electron transporting layer ETL, and an electron injecting layer EIL (not shown) in the stated order from the pixel electrode AD side.

The second reflective film REF2 is formed on the electron injecting layer EIL in the BE pixel second region B-PIX. The second reflective film REF2 is formed of aluminum with a thickness of 200 nm by mask deposition. The second reflective film REF2 connects an adjacent BE pixel second region B-PIX therewith to be formed as an integrated pattern. Accordingly, an auxiliary electrode of a lateral stripe having a width of one pixel is arranged every two pixels.

The common electrode CD is formed on the organic EL layer OEL and the second reflective film REF2, and formed of IZO to have a pattern which covers all the pixels in an integrated manner. The common electrode CD functions as a cathode. As described above, the second reflective film REF2 functions as auxiliary wiring for reducing a sheet resistance of the common electrode CD, and therefore it is less liable to cause in-plane luminance fluctuation in a display surface, thereby improving image quality. In particular, in this embodiment, the auxiliary wiring can be formed, which has a width several times larger than in the cases of conventional technologies where the auxiliary electrode is arranged only on the pixel isolation film. Accordingly, the in-plane luminance fluctuation due to voltage drop can be suppressed.

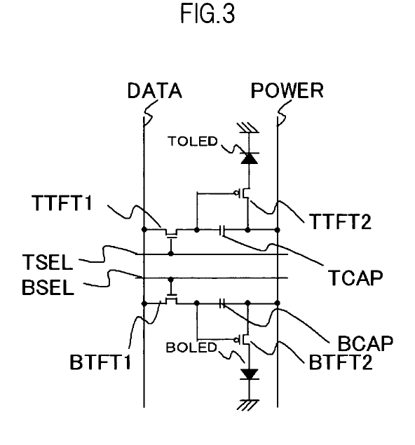

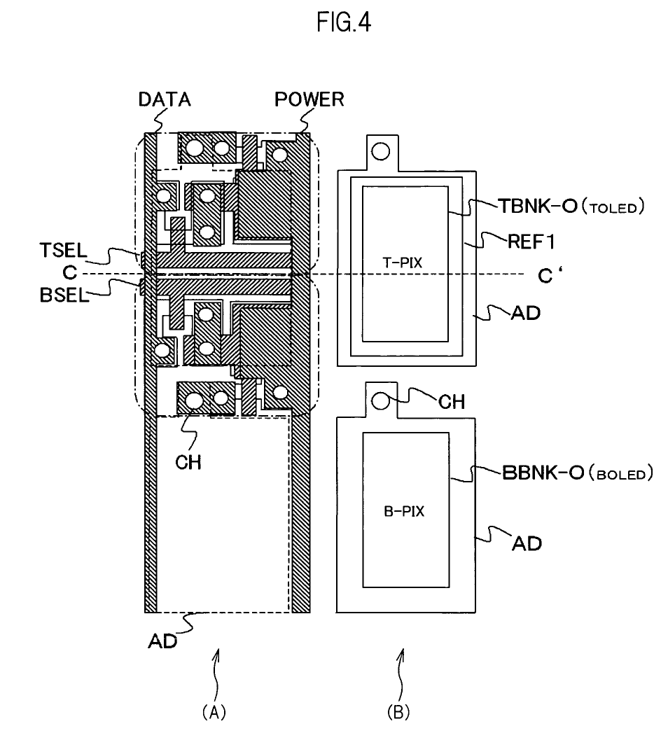

FIG. 3 shows an equivalent circuit diagram of a double-sided light emitting pixel. FIG. 4 shows plan layouts of the double-sided light emitting pixel. The left portion of FIG. 4A is a top view of the laminated body finished up to the step of patterning of the second interlayer insulating film INS2 of FIG. 2, and the right portion of FIG. 4B is a top view of the laminated body finished up to the step of patterning of the pixel isolation film BNK of FIG. 2.

First, the equivalent circuit of a combination-type double-sided light emitting pixel shown in FIG. 3 is described. A lower side of the figure is a BE pixel and an upper side thereof is a TE pixel. A data line DATA extending in a column (longitudinal) direction of a screen and a power source line POWER extending in the column (longitudinal) direction of the screen are alternately arranged in a row (lateral) direction of the screen. A TE pixel selection line TSEL extending in the row (lateral) direction of the screen and a BE pixel selection line BSEL extending in the row (lateral) direction of the screen are alternately arranged in the column (longitudinal) direction of the screen.

On the assumption that a pair of the TE pixel and BE pixel is a unit, the selection lines BSEL and TSEL are arranged one by one in the column direction, and the data line DATA and the power source line POWER are arranged one by one in the row direction.

The data line DATA is supplied with a BE pixel data signal and a TE pixel data signal, which indicate a gradation level. The selection lines BSEL and TSEL are supplied with a scan signal which is a timing signal for importing a video signal in a pixel. The power source line POWER is supplied with an anode potential such that the organic EL element is set to cathode ground.

A pixel circuit B-CIR that drives a BE pixel organic EL element BOLED includes a BE pixel data latch transistor BTFT1, a BE pixel capacitor BCAP, and a BE pixel drive transistor BTFT2.

The BE pixel data latch transistor BTFT1 is turned on according to the selection signal supplied to the BE pixel selection line BSEL and imports a gradation voltage which is a video signal flowing through the data line DATA. After that, the BE pixel data latch transistor BTFT1 is turned off to cause the BE pixel capacitor BCAP to hold a potential difference between the gradation voltage and the power source line POWER. Therefore, on a channel region of the BE pixel data latch transistor BTFT1, a gate electrode is composed of a part of the BE pixel selection line BSEL, the data line DATA is connected with a drain region thereof, and one end of the BE pixel capacitor BCAP is connected with a source region thereof. An n-channel transistor is employed as the BE pixel data latch transistor BTFT1 from the viewpoint of transistor characteristics, but a p-channel transistor may also be used.

The one end of the BE pixel capacitor BCAP is connected with the source region of the BE pixel data latch transistor BTFT1, and is also connected with a gate of the BE pixel drive transistor BTFT2. Another end of the BE pixel capacitor BCAP is connected with the power source line POWER and a source region of the BE pixel drive transistor BTFT2.

The BE pixel drive transistor BTFT2 controls an amount of current supplied from the power source line POWER to the BE pixel organic EL element BOLED according to the potential difference held in the BE pixel capacitor BCAP. Therefore, the gate which is a control end of the BE pixel drive transistor BTFT2 is connected with the one end of the BE pixel capacitor BCAP, a source region thereof is connected with the power source line POWER, and a drain region thereof is connected with the BE pixel organic EL element BOLED. A p-channel transistor is employed as the BE pixel drive transistor BTFT2 from the viewpoint of transistor characteristics, but an n-channel transistor may also be used. In the case of the n-channel transistor, the pixel electrode AD is assumed to be a cathode and the laminating order of the organic EL layer is inverted.

A pixel circuit T-CIR that drives a TE pixel organic EL element TOLED includes a TE pixel data latch transistor TTFT1, a TE pixel capacitor TCAP, and a TE pixel drive transistor TTFT2.

The TE pixel data latch transistor TTFT1 is turned on according to the selection signal supplied to the TE pixel selection line TSEL and imports a gradation voltage which is video data flowing through a TE pixel data line. After that, the TE pixel data latch transistor TTFT1 is turned off to cause the TE pixel capacitor TCAP to hold a potential difference between the gradation voltage and the power source line POWER. Therefore, on a channel region of the TE pixel data latch transistor TTFT1, a gate electrode is composed of a part of the TE pixel selection line TSEL, the data line DATA is connected with a drain region thereof, and one end of the TE pixel capacitor TCAP is connected with a source region thereof. An n-channel transistor is employed as the TE pixel data latch transistor TTFT1 from the viewpoint of transistor characteristics, but a p-channel transistor may also be used.

The one end of the TE pixel capacitor TCAP is connected with the source region of the TE pixel data latch transistor TTFT1, and is also connected with a gate of the TE pixel drive transistor TTFT2. Another end of the TE pixel capacitor TCAP is connected with the power source line POWER and a source region of the TE pixel drive transistor TTFT2.

The TE pixel drive transistor TTFT2 controls an amount of current supplied from the power source line POWER to the TE pixel organic EL element TOLED according to the potential difference held in the TE pixel capacitor TCAP.

Therefore, the gate which is a control end of the TE pixel drive transistor TTFT2 is connected with the one end of the TE pixel capacitor TCAP, a source region thereof is connected with the power source line POWER, and a drain region thereof is connected with the TE pixel organic EL element TOLED. A p-channel transistor is employed as the TE pixel drive transistor TTFT2 from the viewpoint of transistor characteristics, but an n-channel transistor may also be used. In the case of the n-channel transistor, the pixel electrode AD is assumed to be a cathode and the laminating order of the organic EL layer is inverted.

Next, plan layouts are described.

As shown in FIG. 4, the pixel circuit T-CIR that drives the TE pixel organic EL element TOLED is arrange in an upper half of the TE pixel, and the pixel circuit B-CIR that drives the BE pixel organic EL element BOLED is arranged in a lower half of the TE pixel. With this layout, an area of a non-aperture portion can be reduced, resulting in improvement of the aperture ratio.

Specifically, the circuits of this embodiment are vertically line-symmetric with respect to the central line C-C′ which is located on the center in a vertical direction of the TE pixel first region T-PIX of FIG. 4 and extends in the row direction. This is a suitable pattern for identically aligning positions of contact holes for connecting the pixel electrode AD and lower wiring. If the same pattern for the contact holes can be adopted for the TE pixel and the BE pixel, there are merits in that the same pattern for the pixel electrodes AD can also be adopted for both of the TE pixel and the BE pixel, wiring loads in the pixel circuits can be approximated, and the like. Note that there is a case where characteristics of the TE pixel organic EL element TOLED and the BE pixel organic EL element BOLED are different. When those elements are controlled by the pixel circuits, a channel width and a channel length of the TE pixel drive transistor TTFT2 may be changed to lose the symmetry.

The layouts of FIG. 4 are described in more detail. The TE pixel selection line TSEL is arranged immediately above the central line C-C′ which is located on the center in a vertical direction of the TE pixel first region T-PIX and extends in the row direction. The BE pixel selection line BSEL is arranged immediately below the central line C-C′.

The TE pixel selection line TSEL has a protrusion in an upward direction of the figure, and the BE pixel selection line BSEL has a protrusion in-a downward direction of the figure.

A polysilicon layer FG is arranged below the protrusions. In the polysilicon layer FG, one exposed portion thereof exposed from the protrusion is connected with the data line DATA via the contact hole. Another exposed portion thereof is connected with the wiring of the source-drain metal layer SD via the contact hole and further connected with the wiring of the metal gate electrode layer SG. With this structure, the TE pixel data latch transistor TTFT1 and the BE pixel data latch transistor BTFT1 are formed in the region where the protrusions exist.

The wiring of the metal gate electrode layer SG which is connected with the TE pixel data latch transistor TTFT1 and the BE pixel data latch transistor BTFT1 is arranged below wider portions of the power source line POWER. In this superimposed portion, the BE pixel capacitor BCAP and the TE pixel capacitor TCAP are formed. Further, a part of the metal gate electrode layer SG has a protrusion. The polysilicon layer FG is arranged below the protrusion. This superimposed portion forms the channel portions of the BE pixel drive transistor BTFT2 and the TE pixel drive transistor TTFT2. In other words, the protrusion of the metal gate electrode layer SG becomes the gate electrode.

In the polysilicon layer FG, one exposed portion thereof exposed from the protrusion is connected with the power source line POWER via the contact hole. Another exposed portion thereof exposed from the protrusion is connected with the pixel electrode AD via a contact hole, the wiring and a contact hole of the source-drain metal layer SD.

The same pattern for the pixel electrode AD is used for the TE pixel first region T-PIX and the BE pixel second region B-PIX. In addition, patterns for aperture portions TBNK-O and BBNK-O of the pixel isolation film BNK are the same. The first reflective film is patterned such that a boundary is arranged between the pixel electrode AD of the TE pixel first region T-PIX and the aperture portion TBNK-O of the pixel isolation film BNK of the TE pixel. Note that the patterns of the pixel electrodes AD and the aperture patterns of the pixel isolation film BNK between the TE pixel and the BE pixel may not be necessarily the same.

### Second Embodiment

In a second embodiment of the present invention, the plan layouts of the BE pixel and the TE pixel, and the laminated structure of the two pixels including the BE pixel and the TE pixel, which are shown in FIG. 1A, FIG. 1B, and FIG. 2, are the same as in the first embodiment of the present invention. The second embodiment of the present invention is different from the first embodiment of the present invention in the structure of the pixel circuit (equivalent circuit and plan layout) shown in FIG. 3 and FIG. 4. Hereinafter, the structure of the pixel circuit is described.

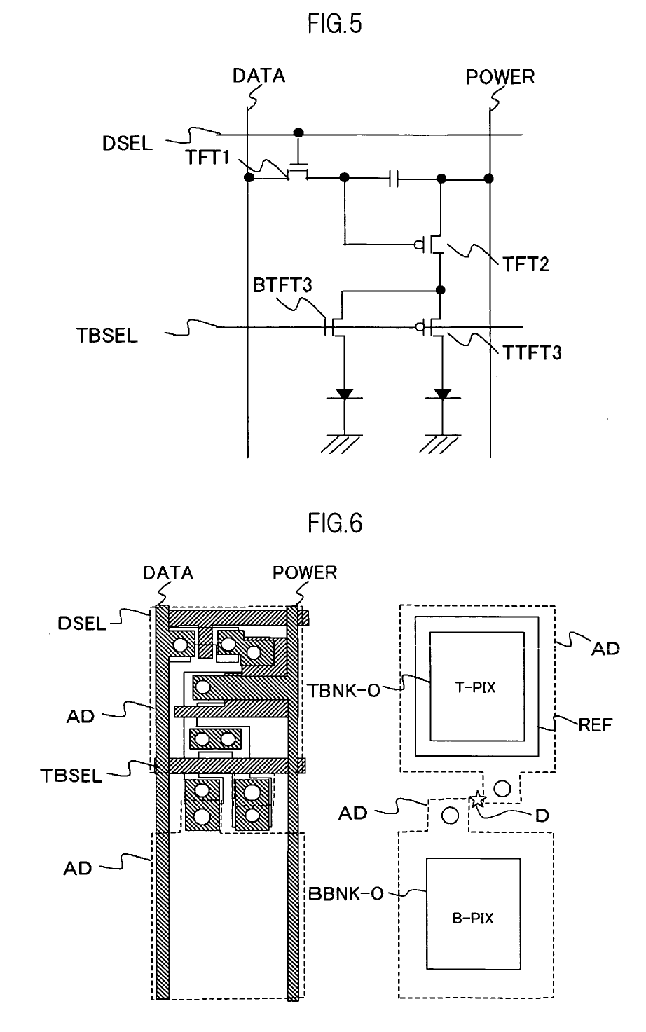

FIG. 5 shows an equivalent circuit diagram of the pixel circuit for a double-sided light emitting pixel. FIG. 6 shows plan layouts of the double-sided light emitting pixel. The left portion of FIG. 6A is a top view of a laminated body finished up to the step of patterning of the second interlayer insulating film INS2, and the right portion of FIG. 6B is a top view of the laminated body finished up to the step of aperture-patterning of the pixel isolation film BNK.

FIG. 5 shows the equivalent circuit diagram of the pixel circuit for a combination-type double-sided light emitting pixel. A lower side of the page is a BE pixel and an upper side thereof is a TE pixel. A data line DATA and a power source line POWER extending in a column (longitudinal) direction of a screen are alternately arranged in a row (lateral) direction of the screen. A pixel selection line DSEL and a BE-TE selection line TBSEL extending in the row (lateral) direction of the screen are alternately arranged in the column (longitudinal) direction of the screen.

The data line DATA is supplied with a video signal and the power source line POWER is supplied with an anode potential. The pixel selection line DSEL is supplied with a selection signal (scan pulse) for determining a timing for importing the video signal for every two pixels combining the BE pixel and the TE pixel.

The BE-TE selection line TBSEL is supplied with a selection signal (scan pulse) for determining a switching timing as to whether current is supplied to the BE pixel or the TE pixel.

The pixel circuit for the two pixels including the BE pixel and the TE pixel has four thin film transistors TFT and a capacitor DCAP.

A first thin film transistor TFT1 is a data latch TFT for importing a video signal into the pixel circuit. A drain region of the first thin film transistor TFT1 is connected with the data line DATA and a gate region thereof is connected with the pixel selection line DSEL. A source region of the first thin film transistor TFT1 is connected with one end of the capacitor DCAP and a gate of a second thin film transistor TFT2. The first thin film transistor TFT1 is an n-channel MOS transistor.

Another end of the capacitor DCAP is connected with the power source line POWER and a gate of the second thin film transistor TFT2.

The second thin film transistor TFT2 is a drive transistor. Therefore, the source region of the second thin film transistor TFT2 is connected with the power source line POWER. A drain region of the second thin film transistor TFT2 is connected with a source region of a BE third thin film transistor BTFT3 and a source region of a TE third thin film transistor TTFT3. The second thin film transistor TFT2 is a pMOS transistor.

The BE third thin film transistor BTFT3 is a switch for determining whether or not current is supplied from the power source line POWER to the BE pixel organic EL element BOLED.

The TE third thin film transistor TTFT3 is a switch for determining whether or not current is supplied from the power source line POWER to the TE pixel organic EL element TOLED.

The BE third thin film transistor BTFT3 is a pMOS transistor and the TE third thin film transistor TTFT3 is an nMOS transistor. Therefore, the BE third thin film transistor BTFT3 and the TE third thin film transistor TTFT3 are turned on alternatively.

A gate region of the BE third thin film transistor BTFT3 and a gate region of the TE third thin film transistor TTFT3 are connected with the BE-TE selection line TBSEL. A drain region of the BE third thin film transistor BTFT3 is connected with the BE pixel organic EL element BOLED and a drain region of the TE third thin film transistor TTFT3 is connected with the TE pixel organic EL element TOLED.

As described above, functions of the first thin film transistor TFT1, the second thin film transistor TFT2, and the capacitor DCAP are shared between the TE pixel circuit and the BE pixel circuit.

Subsequently, the plan layouts are described.

As shown in FIG. 6, an upper half thereof is the TE pixel first region T-PIX and a lower half thereof is a BE pixel second region B-PIX. The pixel circuit that drives the TE pixel organic EL element TOLED of the TE pixel first region T-PIX and the pixel circuit that drives the BE pixel organic EL element BOLED of the BE pixel second region B-PIX are arranged in an upper half of the TE pixel first region T-PIX. With this layout, a light emitting area of the TE pixel organic EL element TOLED can be enlarged.

Specifically, the circuit of this embodiment is a circuit in which the pixel electrode AD of the TE pixel first region T-PIX and the pixel electrode AD of the BE pixel second region B-PIX have an electrode pattern which is point-symmetric with respect to a reference point D located between the TE pixel first region T-PIX and the BE pixel second region B-PIX of FIG. 6 at the center in a lateral direction. In other words, the contact holes connected with the pixel circuits are arranged every two rows of the boundary between the TE pixel first region T-PIX and the BE pixel second region B-PIX.

In the upper portion of the TE pixel of the figure, the pixel selection line DSEL extending in the row direction is arranged on the metal gate electrode layer SG. In the central portion of the TE pixel, the BE-TE selection line TBSEL extending in the row direction is arranged on the metal gate electrode layer SG.

In the left periphery of the TE pixel first region T-PIX and the BE pixel second region B-PIX, the data line DATA extends in the column direction on the source-drain metal layer SD. In the right periphery of the TE pixel first region T-PIX and the BE pixel second region B-PIX, the power source line POWER extends in the column direction on the source-drain metal layer SD.

The pixel selection line DSEL has a protrusion which becomes the gate electrode of the first thin film transistor TFT1 between the data line DATA and the power source line POWER extending in the column direction. The protrusion extends toward the center of the pixel, and connects the source region (polysilicon) of the first thin film transistor TFT1 with metal wiring of the source-drain metal layer SD via the contact hole. The metal wiring of the source-drain metal layer SD is connected with metal wiring of the metal gate electrode layer SG via the contact hole. The metal wiring of the metal gate electrode layer SG is arranged so as to pass below the wider portion of the power source line POWER to construct the capacitor DCAP in the superimposed portion. The wider portion of the power source line POWER is connected with a polysilicon layer via the contact hole. The polysilicon layer extends in the column direction and goes below the metal wiring of the metal gate electrode layer SG halfway. In the portion below the metal wiring of the metal gate electrode layer SG, the second thin film transistor TFT2 is formed. The polysilicon layer which goes below the second thin film transistor TFT2 is branched into two and each of the branched polysilicon layers further extends toward a lower side in the column direction. The branched polysilicon layers go below the BE-TE selection line TBSEL, and are connected with the source-drain metal layer SD at the lower side of the BE-TE selection line TBSEL in the column direction via the contact holes. Further, the contact holes are arranged at positions where arrangement positions are shifted to connect the branched polysilicon layers with the pixel electrodes AD. At two intersecting portions of the BE-TE selection line TBSEL and the branched polysilicon layers FG, the BE third thin film transistor BTFT3 and the TE third thin film transistor TTFT3 are formed. At a part of the branched polysilicon layers FG, a redundant wiring structure connected via a plurality of the contact holes is arranged on the source-drain metal layer SD.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic electroluminescence display device having a substrate, comprising on a surface of the substrate:
a first organic electroluminescence element of a top emission type;
a second organic electroluminescence element of a bottom emission type;
a first circuit that drives the first organic electroluminescence element; and
a second circuit that drives the second organic electroluminescence element,
wherein the second circuit is arranged below the first organic electroluminescence element.

2. An organic electroluminescence display device according to claim 1, wherein:
the first organic electroluminescence element comprises a first reflective film below a light emitting layer;
the second organic electroluminescence element comprises a second reflective film on the light emitting layer; and
the second circuit is arranged below the first reflective film.

3. An organic electroluminescence display device according to claim 2, wherein the first circuit is arranged below the first reflective film.

4. An organic electroluminescence display device having a substrate, comprising on a surface of the substrate:
a first pixel including a first organic electroluminescence element of a top emission type;
a second pixel including a second organic electroluminescence element of a bottom emission type;
a first circuit that drives the first organic electroluminescence element; and
a second circuit that drives the second organic electroluminescence element,
wherein the second circuit is arranged within the first pixel.

5. An organic electroluminescence display device according to claim 4, wherein:
the first pixel comprises a first reflective film in a portion below a light emitting layer;
the second pixel comprises the second reflective film in a portion above the light emitting layer; and
the second circuit is arranged below the first reflective film.

6. An organic electroluminescence display device according to claim 5, wherein the first circuit is arranged below the first reflective film.
